(19) United States
(12) Patent Application Publication
(10) Pub. No.: US 2024/0392476 A1
(43) Pub. Date: Nov. 28, 2024

(54) METHOD FOR TRANSFERRING A MONOCRYSTALLINE SIC LAYER ONTO A POLYCRYSTALLINE SIC CARRIER USING A POLY CRYSTALLINE SIC INTERMEDIATE LAYER

(71) Applicant: Soitec, BERNIN (FR)

(72) Inventors: Ionut Radu, BERNIN (FR); Hugo Biard, BERNIN (FR); Gweltaz Gaudin, BERNIN (FR)

(21) Appl. No.: 18/694,796

(22) PCT Filed: Oct. 3, 2022
(86) PCT No.: PCT/FR2022/051860

§ 371 Date: Mar. 22, 2024

(30) Foreign Application Priority Data
Oct. 5, 2021 (FR) FR2110520

(51) Int. Cl. C30B 33/06; C30B 28/14; C30B 29/36; C30B 33/02

(52) U.S. Cl. CPC C30B 33/06; C30B 28/14; C30B 29/36; C30B 33/02

(57) ABSTRACT

A method of fabricating a composite structure including a thin layer of single-crystal silicon carbide on a polycrystalline SiC carrier substrate includes: forming a polycrystalline SiC layer on a donor substrate, at least a surface portion of which is made of single-crystal SiC; before or after forming the polycrystalline SiC layer, implanting ionic species into the surface portion of the donor substrate, so as to form a plane of weakness delimiting a thin single-crystal SiC layer to be transferred; after the implanting of the ionic species and the forming of the polycrystalline SiC layer, bonding the donor substrate and the polycrystalline SiC carrier substrate, the polycrystalline SiC layer being at the bonding interface; and detaching the donor substrate along the plane of weakness, so as to transfer the polycrystalline SiC layer and the thin single-crystal SiC layer onto the polycrystalline SiC carrier substrate.

### CROSS-REFERENCE TO RELATED APPLICATIONS

This application is a national phase entry under 35 U.S.C. § 371 of International Patent Application PCT/FR2022/051860, filed Oct. 3, 2022, designating the United States of America and published as International Patent Publication WO 2023/057709 A1 on Apr. 13, 2023, which claims the benefit under Article 8 of the Patent Cooperation Treaty of French Patent Application Serial No. FR2110520, filed Oct. 5, 2021.

### TECHNICAL FIELD

The field of the present disclosure is that of semiconductor materials for microelectronic components. The present disclosure relates more particularly to a process for fabricating a composite structure comprising a thin layer of single-crystal silicon carbide on a carrier substrate made of polycrystalline silicon carbide.

### BACKGROUND

Silicon carbide (SiC) is increasingly widely used in power electronics applications, notably to meet the needs of growing ranges of electronics, such as, for example, electric vehicles. Power devices and integrated power-supply systems based on single-crystal SiC can manage a much higher power density than their conventional silicon counterparts, and do so with active regions of smaller size.

Nevertheless, single-crystal SiC substrates intended for the microelectronics industry remain expensive and difficult to supply in large sizes. It is therefore advantageous to use layer transfer solutions in order to produce composite structures typically comprising a thin layer of single-crystal SiC on a lower cost carrier substrate. One well-known thin-layer transfer solution is the SMART CUT™ process, which is based on implanting light ions and joining by direct bonding. Such a process makes it possible, for example, to fabricate a composite structure comprising a thin layer made of single-crystal SiC, taken from a donor substrate made of single-crystal SiC, in direct contact with a carrier substrate made of polycrystalline SiC.

Nevertheless, it remains difficult to achieve high-quality direct bonding by molecular adhesion between two substrates made of single-crystal SiC and polycrystalline SiC, since managing the surface finish and roughness of the substrates is complex.

Good thermal and electrical conduction between the thin layer made of single-crystal SiC and the carrier substrate made of polycrystalline SiC is required in the targeted applications. Furthermore, the presence of bonding defects at the joining interface is highly detrimental to the quality of the structures produced in the thin layer made of single-crystal SiC. For example, the absence of adhesion between the two surfaces at a bonding defect may lead to the local detachment of the thin-layer at this location during the transfer thereof from the single-crystal SiC substrate to the polycrystalline SiC substrate.

Two solutions for achieving bonding of two substrates made of single-crystal SiC and polycrystalline SiC have been reported in the literature without any evidence being available today regarding their effectiveness on an industrial scale. Thus, on the one hand, surface activated bonding (SAB), which involves activating the surfaces to be joined by argon bombardment typically and, on the other hand, atomic diffusion bonding (ADB), which includes the sputter deposition of an ultra-thin layer and bonding under ultra-high vacuum, are known. These solutions have the drawback of generating an unstable layer at the bonding interface, which is capable of generating bonding defects and of negatively affecting the electrical conduction.

### BRIEF SUMMARY

The objective of the present disclosure is to provide a technique that overcomes these drawbacks in order to provide a composite structure comprising a thin layer of single-crystal SiC of very high quality, in particular, to improve the performance and reliability of the power devices intended to be produced in the thin layer.

For this purpose, the present disclosure provides a process for fabricating a composite structure comprising a thin layer of single-crystal silicon carbide, positioned on a polycrystalline SiC carrier substrate, comprising the following steps:
forming a polycrystalline SiC layer on a donor substrate, at least a surface portion of which is made of single-crystal SiC,
before or after the forming of the polycrystalline SiC layer, implanting ionic species in the surface portion of the donor substrate, so as to form a plane of weakness delimiting a thin single-crystal SiC layer to be transferred,
after the implanting of the ionic species and the forming of the polycrystalline SiC layer, bonding the donor substrate and the polycrystalline SiC carrier substrate, the polycrystalline SiC layer being at the bonding interface, and detaching the donor substrate along the plane of weakness, so as to transfer the polycrystalline SiC layer and the thin single-crystal SiC layer onto the polycrystalline SiC carrier substrate.

Certain preferred but non-limiting aspects of this process are the following:
the polycrystalline SiC layer has a polytype identical to that of the carrier substrate;
the formation of the polycrystalline SiC layer comprises a deposition of polycrystalline SiC;
the deposition of polycrystalline SiC is a chemical vapor deposition;
the deposition of polycrystalline SiC is carried out at a temperature below 1000° C.;
the formation of the polycrystalline SiC layer comprises a deposition of an amorphous SiC layer and a recrystallization annealing applied to the amorphous SiC layer;
the polycrystalline SiC layer deposited on the donor substrate has a thickness of between 10 nm and 10 μm;
the method comprises a thinning and/or a polishing of the surface of the polycrystalline SiC layer intended to be at the bonding interface during the bonding and/or of the surface of the carrier substrate intended to be at the bonding interface during the bonding;
the method further comprises the formation of a bonding layer on each of the donor and carrier substrates, the bonding being carried out by direct bonding of the bonding layers thus formed;
the bonding layer formed on each of the donor and carrier substrates is a metal layer, for example, a layer of tungsten or a layer of titanium;
the bonding layer formed on each of the donor and carrier substrates is a layer of silicon, of carbon or of silicon carbide;
the bonding layer has a melting point below a temperature of an annealing applied during the bonding step.

### BRIEF DESCRIPTION OF THE DRAWINGS

Other aspects, objectives, advantages and features of the present disclosure will become more apparent on reading the following detailed description of example embodiments thereof, given as nonlimiting examples and with reference to the appended drawings in which:

FIG. 1 is a schematic cross-sectional view of a single-crystal SiC donor substrate;

FIG. 2 is a schematic cross-sectional view of the deposition of a polycrystalline SiC layer on the surface of the single-crystal SiC donor substrate.

FIG. 3 is a schematic cross-sectional view of the formation, by implanting ionic species, of a plane of weakness in the donor substrate of FIG. 1 in order to delimit a thin single-crystal SiC layer to be transferred;

FIG. 4 is a schematic cross-sectional view of the joining of the donor substrate of FIG. 2 and of a carrier substrate;

FIG. 5 is a schematic cross-sectional view of the detachment of the donor substrate along the plane of weakness in order to transfer the thin single-crystal SiC layer to the carrier substrate.

### DETAILED DESCRIPTION

The present disclosure relates to a process for fabricating a composite structure comprising a thin layer of single-crystal SiC positioned on a polycrystalline SiC carrier substrate. This process comprises the transfer, in accordance with the SMART CUT™ process, of the thin layer of single-crystal SiC to the carrier substrate from a donor substrate, at least a surface portion of which is made of single-crystal SiC.

The donor substrate may be a bulk substrate of single-crystal SiC. In other embodiments, the donor substrate may be a composite substrate, comprising a surface layer of single-crystal SiC and at least one other layer of another material. In this case, the single-crystal SiC layer will have a thickness greater than or equal to 0.5 μm.

According to the present disclosure, provision is made to form a polycrystalline SiC layer on the donor substrate before the bonding with the polycrystalline SiC carrier substrate. In such a way, the bonding interface is created between materials having the same morphology (namely two polycrystalline SiC), instead of a heterogeneous crystalline structure (namely a single-crystal SiC added to polycrystalline SiC). The drawbacks linked to the bonding of these heterogeneous crystalline structures are thus avoided. Notably, the present disclosure makes it possible to not create a conduction barrier at the bonding interface and to have a contact area that is not reduced due to the formation of cavities at the bonding interface.

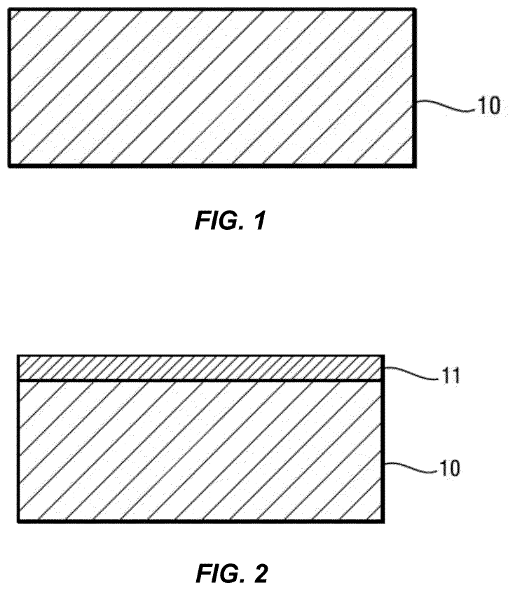

With reference to FIG. 1, the process according to the present disclosure begins with the provision of a donor substrate 10, at least a surface portion of which is made of single-crystal SiC. In the figures, a donor substrate 10 of single-crystal SiC has been shown.

With reference to FIG. 2, the process comprises the step of forming a polycrystalline SiC layer 11 on the donor substrate 10. The polycrystalline SiC layer 11 formed on the donor substrate preferably has a thickness of between 10 nm and 10 μm, even more preferably a thickness of less than 50 nm.

The size of the grains of the polycrystalline SiC layer 11 is preferably less than 30 nm, even more preferably less than 10 nm, which makes it possible to limit the surface roughness of the layer 11 thus deposited. Such a reduced grain size additionally offers the advantage that the conditions for forming the polycrystalline SiC layer 11 can approach those for an amorphous SiC layer, the layer 11 formed thus being able to be a mixture of small grains and a high proportion of amorphous SiC without this being detrimental to the effects of the present disclosure.

There are various crystal forms (also called polytypes) of silicon carbide. The most common are the forms 4H, 6H and 3C. Preferably, the formation of the polycrystalline SiC layer 11 is carried out so as to give it the same polytype as that of the carrier substrate 20, generally a 3C polytype.

In one possible embodiment, the polycrystalline SiC layer is formed by deposition of polycrystalline SiC. Such a deposition of a polycrystalline SiC layer may be a physical vapor deposition (for example, of Electron Beam Physical Vapor Deposition (EBPVD) type) or a chemical vapor deposition (for example, of Direct Liquid Injection Chemical Vapor Deposition (DLI-CVD) type). In one possible embodiment, the deposition of the polycrystalline SiC layer is carried out at a temperature below 1000° C., preferably below 900° C., even more preferably below 850° C. This embodiment proves particularly advantageous when the deposition of the polycrystalline SiC layer 11 is carried out after the implantation of ionic species described below for forming a plane of weakness in the donor substrate. This relatively low temperature specifically makes it possible to limit the growth of the cavities present in the plane of weakness, which growth, in the absence of a stiffening effect provided to the donor substrate, results in the deformation of the layer directly in line with the cavities and the appearance of the blistering phenomenon.

In one embodiment variant that may, in particular, be used when the implantation of ionic species described below is carried out after the formation of the polycrystalline SiC layer 11, the formation of the polycrystalline SiC layer firstly comprises the deposition of a layer of (completely or partly) amorphous SiC then a recrystallization annealing, typically at a temperature above 1100° C., that converts the layer of amorphous SiC into a polycrystal constituting the polycrystalline SiC layer 11.

In one possible embodiment, the formation of the polycrystalline SiC layer 11 is accompanied by the formation of a bonding layer on the polycrystalline SiC layer 11 and on the carrier substrate, respectively, for example, a layer of silicon, of carbon or of silicon carbide or else a metal layer, for example, a layer of tungsten or of titanium. The bonding layers may be formed according to the physical vapor deposition (PVD) process, using, for the gas for ablation of the target, argon or an argon/nitrogen or argon/propane mixture. The bonding layers preferably have a melting point below a temperature of an annealing applied during the bonding step. Thus, for example, bonding layers made of silicon or of titanium are chosen when an annealing at a temperature on the order of 1700° C./1800° C. is applied during the bonding step.

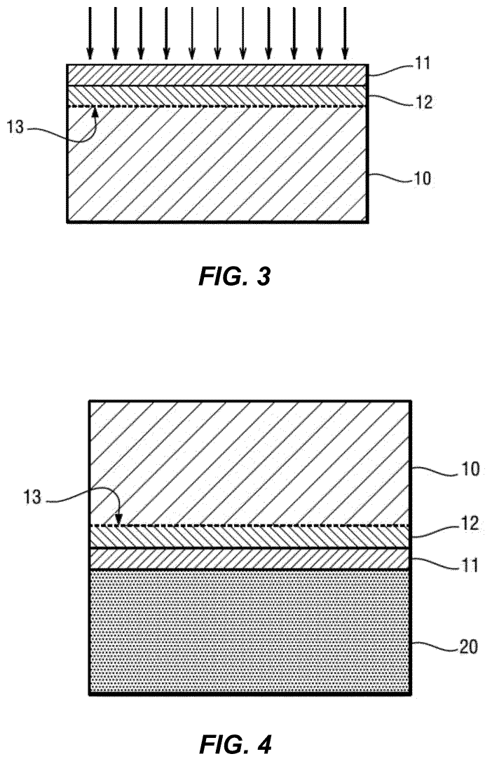

With reference to FIG. 3, the process further comprises, before or after the formation of the polycrystalline SiC layer 11, an implantation of ionic species in the donor substrate 10 so as to form a plane of weakness 13 delimiting a thin single-crystal SiC layer 12 to be transferred. In the figures, the implantation is carried out after the deposition of the polycrystalline SiC layer 11.

The implanted species typically comprise hydrogen and/or helium. A person skilled in the art will be able to define the required implantation dose and energy.

When the donor substrate is a composite substrate, the implantation is carried out so as to form the plane of weakness in the surface layer of single-crystal SiC of the donor substrate.

Preferably, the thin layer 12 of single-crystal SiC has a thickness of less than 1 μm. Specifically, such a thickness is accessible on an industrial scale with the SMART CUT™ process. In particular, the implantation devices available on industrial fabrication lines allow such an implantation depth to be obtained.

With reference to FIG. 4, the process comprises, after the implantation of the ionic species and the formation of the polycrystalline SiC layer 11, the bonding of the donor substrate and of the carrier substrate. The bonding is direct bonding with no intermediate electrically insulating layer, obtained by molecular adhesion of the surfaces brought into contact. The bonding is typically carried out at ambient temperature. The bonding is preferably carried out under vacuum.

During this bonding, the polycrystalline SiC layer 11 previously formed on the donor substrate is at the bonding interface. The expression “layer located at the bonding interface” is understood to mean a layer located on the side of the face of the donor substrate, which is bonded to the carrier substrate but does not necessarily imply direct contact between the layer and the carrier substrate. Thus, the layer may be bonded directly to the carrier substrate or be covered with a bonding layer such as the one mentioned previously with which the bonding is carried out. Bonding by direct contact of polycrystalline layers has the advantage of physically separating the interface between the single-crystal SiC and the polycrystalline SiC of the bonding interface.

This bonding is typically preceded by operations for preparing the surfaces to be bonded, for example, here the two polycrystalline SiC surfaces, such as, for example, a fine polishing, wet or dry cleaning, surface activation, etc. In particular, the process may comprise a thinning and/or a polishing of the surface of the polycrystalline SiC layer 11 intended to be at the bonding interface during the bonding and/or of the surface of the carrier substrate 20 intended to be at the bonding interface during the bonding.

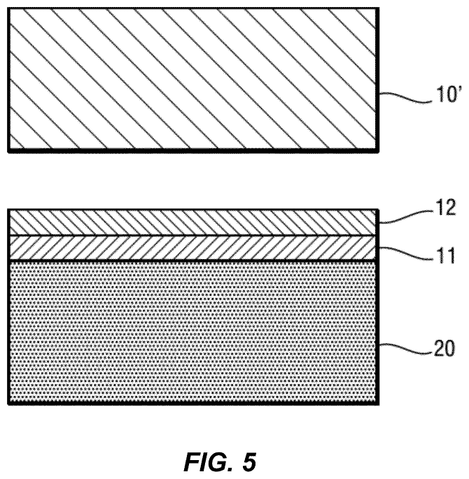

With reference to FIG. 5, the process then comprises the detachment of the donor substrate 10 along the plane of weakness 13 so as to transfer the polycrystalline SiC layer 11 and the thin single-crystal SiC layer 12 onto the carrier substrate 20. In a known manner, this detachment may be caused by a heat treatment, a mechanical action, or a combination of these means. The remainder 10′ of the donor substrate may be recycled with a view to another use.

One or more finishing operations may then be applied to the transferred single-crystal SiC layer 12. It is, for example, possible to carry out a smoothing, a cleaning or else a polishing, for example, a chemical-mechanical polishing (CMP) or a fine grinding (which makes it possible to dispense with preferential chemical etchings on such and such grain orientation), in order to remove defects linked to the implantation of the ionic species and reduce the roughness of the transferred single-crystal SiC layer 12.

1. A method of fabricating a composite structure including a thin layer of single-crystal silicon carbide positioned on a polycrystalline SiC carrier substrate, the method comprising the following steps:
forming a polycrystalline SiC layer on a donor substrate, at least a surface portion of which is made of single-crystal SiC;
before or after the forming, implanting ionic species in the surface portion of the donor substrate, so as to form a plane of weakness delimiting a thin single-crystal SiC layer to be transferred;
after the implanting of the ionic species and the forming of the polycrystalline SiC layer, bonding the donor substrate and the polycrystalline SiC carrier substrate, the polycrystalline SiC layer being at the bonding interface; and
detaching the donor substrate along the plane of weakness, so as to transfer the polycrystalline SiC layer and the thin single-crystal SiC layer onto the polycrystalline SiC carrier substrate.

2. The method of claim 1, further comprising forming the polycrystalline SiC layer to have a polytype identical to a polytype of the carrier substrate.

3. The method of claim 1, wherein the forming of the polycrystalline SiC layer comprises depositing the polycrystalline SiC layer.

4. The method of claim 3, in wherein the depositing of the polycrystalline SiC layer comprises depositing the polycrystalline SiC layer using chemical vapor deposition.

5. The method of claim 3, further comprising performing the depositing of the polycrystalline SiC layer at a temperature below 1000° C.

6. The method of claim 1, wherein the forming of the polycrystalline SiC layer comprises depositing an amorphous SiC layer and annealing the amorphous SiC layer to crystallize the SiC layer.

7. The method of claim 1, wherein the forming of the polycrystalline SiC layer comprises forming the polycrystalline SiC layer to have a thickness between 10 nm and 10 μm.

8. The method of claim 1, further comprising thinning and/or polishing the surface of the polycrystalline SiC layer and/or of the surface of the carrier substrate prior to the bonding of the donor substrate and the polycrystalline SiC carrier substrate.

9. The method of claim 1, further comprising forming a first bonding layer the donor substrate and forming a second bonding layer on the polycrystalline SiC carrier substrate, and wherein the bonding of the donor substrate and the polycrystalline SiC carrier substrate comprises direct bonding of the first bonding layer and the second bonding layer.

10. The method of claim 9, further comprising forming each of the first bonding layer and the second bonding layer to comprise a metal layer.

11. The method of claim 9, further comprising forming each of the first bonding layer and the second bonding layer to comprise a layer of silicon, carbon or silicon carbide.

12. The method of claim 9, wherein the bonding of the donor substrate and the polycrystalline SiC carrier substrate comprises thermally annealing the donor substrate and the polycrystalline SiC carrier substrate at an elevated temperature; and wherein the method further comprises forming each of the first bonding layer and the second bonding layer to comprise a material having a melting point below the elevated temperature of the thermally annealing.

13. The method of claim 10, further comprising forming each of the first bonding layer and the second bonding layer to comprise a layer of tungsten or a layer of titanium.

14. The method of claim 2, wherein the forming of the polycrystalline SiC layer comprises forming the polycrystalline SiC layer to have a thickness between 10 nm and 10 μm.

15. The method of claim 14, wherein the forming of the polycrystalline SiC layer comprises depositing the polycrystalline SiC layer.

16. The method of claim 15, wherein the depositing of the polycrystalline SiC layer comprises depositing the polycrystalline SiC layer using chemical vapor deposition.

17. The method of claim 16, further comprising performing the depositing of the polycrystalline SiC layer at a temperature below 1000° C.

18. The method of claim 17, further comprising thinning and/or polishing the surface of the polycrystalline SiC layer and/or of the surface of the carrier substrate prior to the bonding of the donor substrate and the polycrystalline SiC carrier substrate.

19. The method of claim 17, further comprising forming a first bonding layer the donor substrate and forming a second bonding layer on the polycrystalline SiC carrier substrate, and wherein the bonding of the donor substrate and the polycrystalline SiC carrier substrate comprises direct bonding of the first bonding layer and the second bonding layer.

20. The method of claim 14, wherein the forming of the polycrystalline SiC layer comprises depositing an amorphous SiC layer and annealing the amorphous SiC layer to crystallize the SiC layer.
